(19) United States
(12) Patent Application Publication
(10) Pub. No.: US 2010/0013092 A1
(43) Pub. Date: Jan. 21, 2010

(54) Semiconductor device and manufacturing method therefor

(75) Inventor: Tsuyoshi Eda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONIC CORPORATION, Kawasaki (JP)

(21) Appl. No.: 12/458,328

(22) Filed: Jul. 8, 2009

(30) Foreign Application Priority Data
Jul. 18, 2008 (JP) 187222/2008

(51) Int. Cl. H01L 23/498; H01L 21/768

(52) U.S. Cl. 257/737; 438/613; 257/E21.575; 257/E23.068; 257/E23.072

(57) ABSTRACT

Provided is a semiconductor device having a bump structure which is capable of resolving inconvenience in mounting. The semiconductor device comprises: an electrode pad; and a columnar bump formed on the electrode pad, the columnar bump comprising: a first high melting point metal layer (14) formed on the electrode pad; a first solder (15) formed on the first high melting point metal layer (14); a second high melting point metal layer (16) formed on the first solder (15); and a second solder (17) which is formed on the second high melting point metal layer (16) and is connected to an external.

### BACKGROUND OF THE INVENTION

1. Field of the Invention

The present invention relates to a semiconductor device and a manufacturing method therefor, and more particularly, to a bump structure of a semiconductor device.

2. Description of the Related Art

FIG. 10 illustrates a conventional solder bump structure. As illustrated in FIG. 10, a polyimide 2 is formed on an uppermost layer metal 1. An opening is formed so that the uppermost layer metal 1 is exposed. A sputtered film 3 and an under bump metal (UBM) 4 are laminated in the opening, and a solder 5 is provided thereon.

As the process goes through generations, a bump diameter and a bump pitch (distance between bumps) have become smaller. When a solder bump is reflowed, the solder bump is melted and a width of the solder bump becomes larger. Hence, it is necessary to reduce an amount of solder as the bump pitch decreases for the purpose of preventing a short circuit between bumps.

However, reducing the amount of the solder results in a decreased standoff (distance between a chip and amounting board in flip-chip mounting), which increases a risk of generation of voids (air bubbles) when an underfill resin is injected between the chip and the mounting board.

Instead of the solder bump structure, a columnar bump structure is capable of decreasing the bump pitch while maintaining the standoff. The columnar bump structure is a structure in which a solder layer is formed on a column made of a high melting point metal such as Cu.

However, even the columnar bump structure has a weak point. Most of the columnar bump structure is made up of a high melting point metal such as Cu. Therefore, due to stresses produced in flip-chip mounting (reflow), breakage of the bump may occur. Therefore, when the columnar bump structure is applied to a product, from the viewpoint of improving yield and reliability, some measures to improve stress tolerance are necessary.

As illustrated in Japanese Patent Application Laid-open No. Hei 6-333931, a columnar bump has a structure in which a solder layer is formed on a high melting point metal which has excellent conductivity such as Cu. A thickness of the solder layer is determined by design. When an amount of the solder is large, as illustrated in Japanese Patent Application Laid-open No. Hei 6-333931, the solder goes around a periphery of the top to the side of columnar Cu to cover the columnar Cu. On the other hand, as illustrated in FIG. 11, when the amount of the solder is set to be small, a surface tension of the solder 5 makes the solder 5 formed only on the top of a columnar Cu 6.

FIG. 12 is a cross-sectional view of the columnar bump structure after mounting. As illustrated in FIG. 12, an auxiliary solder 8 which is a low melting point solder is provided on a substrate pad 7 on the side of the mounting board. The auxiliary solder 8 and the solder 5 are disposed so as to be opposed to each other. By heating them, soldering is carried out.

In particular, in a product with a large chip size (for example, 15 mm×15 mm or larger), in flip-chip mounting, due to a difference in thermal expansion coefficient between the chip and the mounting board and due to a warp in the mounting board because of heat, vertical and horizontal stresses are applied to a bump positioned on an outer side of the chip.

The solder acts as an alleviator of the stresses in mounting. However, in Japanese Patent Application Laid-open No. Hei 6-333931, in the columnar bump structure, a ratio of the solder, which acts as an alleviator of the stresses in mounting, in the bump is small compared with the case of the solder bump structure. When the ratio of the solder in the bump structure is small, the stresses in mounting cannot be completely alleviated, and breakage (cracks) occurs in regions surrounded by broken lines of FIG. 12 (interface between the bump and the chip) and in a solder portion.

On the other hand, when the amount of the solder is large, the solder is melted so as to cover the columnar Cu, and hence the width of the bump becomes larger. When the bump pitch is small, there is a high risk that a short circuit between bumps occurs, which means application of the structure is difficult. Further, an area occupied by the bump in design becomes larger, and accordingly the structure is not appropriate for a decreased chip size.

Japanese Patent Application Laid-open No. Sho 62-234352 describes a two-layer bump having a high melting point solder as its lower layer and a low melting point solder as its upper layer. The bump described in Japanese Patent Application Laid-open No. Sho 62-234352 is formed only of a solder, and hence resistance of the bump is higher. The resistance of the bump becomes higher as the bump diameter becomes smaller, and hence high resistance due to a material of the bump is not preferable. Further, in reflow, even at a temperature which is lower than a melting point of the high melting point solder, the low melting point solder and the high melting point solder are gradually mixed with each other, and thus, it is difficult to maintain the columnar shape.

As described in the above, the conventional bump structures have a problem that inconvenience is caused in mounting which makes difficult the application thereof.

### SUMMARY OF THE INVENTION

A semiconductor device according to one aspect of the present invention comprises: an electrode pad; and a columnar bump formed on the electrode pad, the columnar bump comprising: a first high melting point metal layer formed on the electrode pad; a first solder formed on the first high melting point metal layer; a second high melting point metal layer formed on the first solder; and a second solder which is formed on the second high melting point metal layer and is connected to an external. This makes it possible to increase a ratio of the solder in the columnar bump, to alleviate stresses in mounting, and to suppress breakage of the bump.

A semiconductor device according to another aspect of the present invention comprises: an electrode pad; and a columnar bump formed on the electrode pad, the columnar bump comprising: a first high melting point metal layer which is formed on the electrode pad, and occupies a half or more of a volume of the columnar bump; a first solder formed on the first high melting point metal layer; and a second solder which is formed on the first solder and is connected to an external. This makes it possible to increase the ratio of the solder in the columnar bump, to alleviate stresses in mounting, and to suppress breakage of the bump.

A semiconductor device according to another aspect of the present invention comprises: an electrode pad; a high melting point metal layer formed on the electrode pad; a first metal layer formed on the high melting point metal layer; and a second metal layer which is formed on the first metal layer, and has a hardness different from a hardness of the first metal layer, the high melting point metal layer, the first metal layer, and the second metal layer forming a columnar bump. This makes it possible to suppress breakage of the bump.

A method of manufacturing a semiconductor device according to another aspect of the present invention comprises forming a columnar bump on an electrode pad, the forming the columnar bump comprising: forming a first high melting point metal layer on the electrode pad; forming a first solder on the first high melting point metal layer; forming a second high melting point metal layer on the first solder; and forming a second solder on the second high melting point metal layer, the second solder being connected to an external. This makes it possible to increase the ratio of the solder in the columnar bump, to alleviate stresses in mounting, and to suppress breakage of the bump.

A method of manufacturing a semiconductor device according to another aspect of the present invention comprises forming a columnar bump on an electrode pad, the forming the columnar bump comprising: forming a first high melting point metal layer on the electrode pad, the first high melting point metal layer occupying a half or more of a volume of the columnar bump; forming a first solder on the first high melting point metal layer; and forming a second solder on the first solder, the second solder being connected to an external. This makes it possible to increase the ratio of the solder in the columnar bump, to alleviate stresses in mounting, and to suppress breakage of the bump.

The present invention can provide the semiconductor device having the bump structure which is capable of resolving inconvenience in mounting, and the manufacturing method therefor.

### BRIEF DESCRIPTION OF THE DRAWINGS

In the accompanying drawings:

FIG. 1 is a cross-sectional view illustrating a structure of a columnar bump before reflow of a semiconductor device according to a first embodiment;

FIG. 2 is a cross-sectional view illustrating the structure of the columnar bump after the reflow of the semiconductor device according to the first embodiment;

FIGS. 3A and 3B are plan views illustrating the structure of the columnar bump of the semiconductor device according to the first embodiment;

FIG. 4 is a cross-sectional view illustrating a state of the semiconductor device according to the first embodiment after mounting;

FIGS. 5A and 5B are cross-sectional views illustrating manufacturing steps of a method of manufacturing the semiconductor device according to the first embodiment;

FIGS. 6C and 6D are cross-sectional views illustrating manufacturing steps of the method of manufacturing the semiconductor device according to the first embodiment;

FIG. 7E is a cross-sectional view illustrating a manufacturing step of the method of manufacturing the semiconductor device according to the first embodiment;

FIG. 8 is a cross-sectional view illustrating a structure of a columnar bump before reflow of a semiconductor device according to a second embodiment;

FIG. 9 is a cross-sectional view illustrating a structure of a columnar bump before reflow of a semiconductor device according to a third embodiment;

FIG. 10 is a cross-sectional view illustrating a structure of a solder bump of a conventional semiconductor device;

FIG. 11 is a cross-sectional view illustrating a structure of a columnar bump of a conventional semiconductor device; and

FIG. 12 is a cross-sectional view illustrating a state of the conventional semiconductor device after mounting.

### DETAILED DESCRIPTION OF THE PREFERRED EMBODIMENTS

### First Embodiment

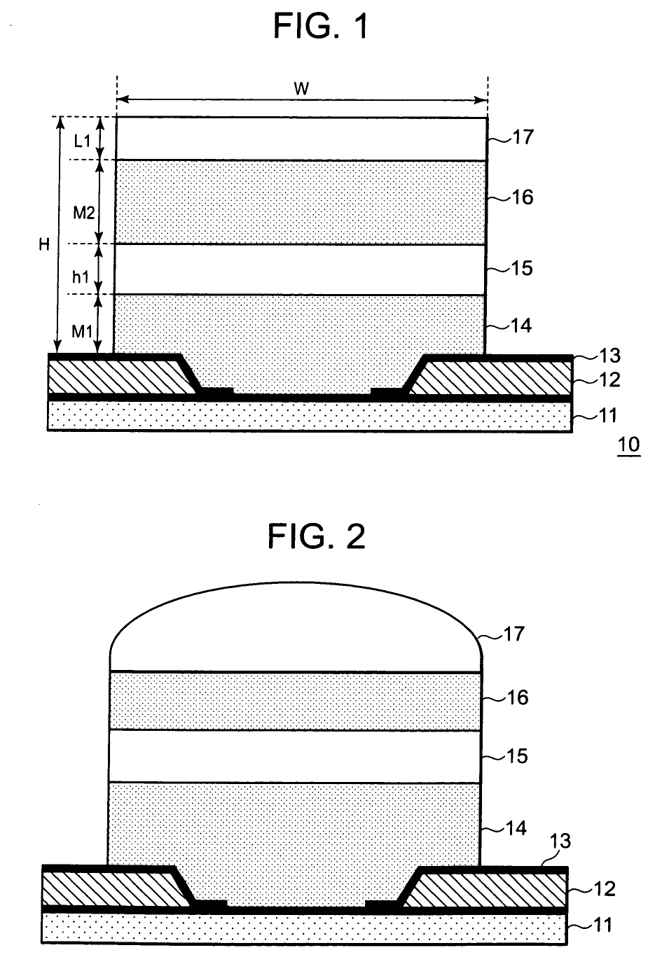

A semiconductor device according to a first embodiment of the present invention is now described with reference to the drawings. FIG. 1 is a cross-sectional view illustrating a structure of a columnar bump before reflow of the semiconductor device according to this embodiment. As illustrated in FIG. 1, a semiconductor device 10 according to this embodiment includes an uppermost layer metal 11, a polyimide 12, a sputtered film 13, a first high melting point metal layer 14, a first solder 15, a second high melting point metal layer 16, and a second solder 17.

The polyimide 12 is formed on the uppermost layer metal 11. An opening for exposing the uppermost layer metal 11 is formed in the polyimide 12. A region in which the opening is formed is to be an electrode pad. The sputtered film 13 is provided on the uppermost layer metal 11 and the polyimide 12 in the opening.

The columnar bump is formed on the electrode pad. The columnar bump has a lamination structure in which the first high melting point metal layer 14, the first solder 15, the second high melting point metal layer 16, and the second solder 17 are laminated in the stated order from the bottom. More specifically, in this embodiment, the columnar bump has a structure in which two two-layer structures each having a high melting point metal layer and a solder laminated therein are stacked. In other words, two high melting point metal layers and two solder layers are alternately laminated.

As the first high melting point metal layer 14 and the second high melting point metal layer 16, a high melting point metal whose resistance is lower than (whose conductivity is higher than) those of the solders may be used. Exemplary high melting point metals which can be used as the first high melting point metal layer 14 and the second high melting point metal layer 16 include Cu and Au. The conductivities of Cu and Au are as follows.

Cu: 59.0E6 (S/m)

Au: 45.5E6 (S/m)

As the first solder 15, a solder having a melting point which is higher than that of the second solder 17 as an uppermost layer is used so as not to be melted in a reflow process at the end of a bump forming process. More specifically, the first solder 15 and the second solder 17 are metal layers having different hardnesses. In particular, it is preferable that the first solder 15 be a metal layer which is softer than the first high melting point metal layer 14. For example, it is preferable that a high melting point solder containing a soft metal such as lead (Pb) be used as the first solder 15.

Exemplary kinds of solder include the following.

### SnAgCu Solder

SnAgCu solders are almost made of Sn and contain about 0.3% of Ag and about 0.5% of Cu. The conductivities of the solders are dominated by the conductivity of Sn, 7.9E6 (S/m). The melting points of the SnAgCu solders are about 230° C.

### SnZnBi Solder

The melting points of SnZnBi solders are lowered by adding Zn and Bi thereto, and are about 180° C. The conductivities of the solders are dominated by the conductivity of Sn, 7.9E6 (S/m)

### Pb Solder

Pb solders contain about 95% of Pb. The melting points of the solders are about 330° C. The conductivity of Pb is 4.8E6 (S/m).

As illustrated in FIG. 1, it is assumed that a thickness of the first high melting point metal layer 14, a thickness of the second high melting point metal layer 16, a thickness of the first solder 15, and a thickness of the second solder 17 are M1, M2, h1, and L1, respectively. The thickness M1 of the first high melting point metal layer 14 and the thickness M2 of the second high melting point metal layer 16 satisfy Equation (1).

M1≧M2 (1)

More specifically, for the purpose of supporting the second high melting point metal layer 16 which is an upper layer by the first high melting point metal layer 14 which is a lower layer, the thickness M1 of the first high melting point metal layer 14 which is the lower layer is set to be substantially equal to or larger than the thickness M2 of the second high melting point metal layer 16 which is the upper layer. This makes it possible to maintain a columnar shape of the columnar bump even after a mounting process, and it is possible to suppress shortening of a distance between a chip and a mounting board in flip-chip mounting (standoff).

Further, for the purpose of suppressing an increase in resistance, the thickness (volume) of the high melting point metal layers is made to be equal to or larger than the thickness (volume) of the solders. More specifically, a sum of the thicknesses of the first high melting point metal layer 14 and the second high melting point metal layer 16 is made to be equal to or larger than a sum of the thicknesses of the first solder 15 and the second solder 17 to satisfy Equation (2).

M1+M2≧h1+L1 (2)

This makes it possible to suppress the increase in resistance due to the columnar bump.

Further, the thickness L1 of the second solder 17 is equal to or smaller than a half of a width (diameter) W of the columnar bump as expressed by Equation (3).

L1≦0.5×W (3)

It is to be noted that, here, a shape of the columnar bump seen from above is substantially a circle and the columnar bump is substantially a circular cylinder.

FIG. 2 illustrates the structure of the columnar bump after the reflow at a bump formation finishing stage. As illustrated in FIG. 2, the second solder 17 as the uppermost layer is once melted in the reflow process to complete the formation of the columnar bump. If the thickness L1 of the second solder 17 is equal to or smaller than a half of the width W of the columnar bump so as to satisfy Equation (3), when the second solder 17 is melted, the melted solder does not go around a periphery of the top to the side of the columnar bump. This can suppress horizontal spread of the solder, and thus, even when a chip size is decreased, a short circuit between bumps can be prevented.

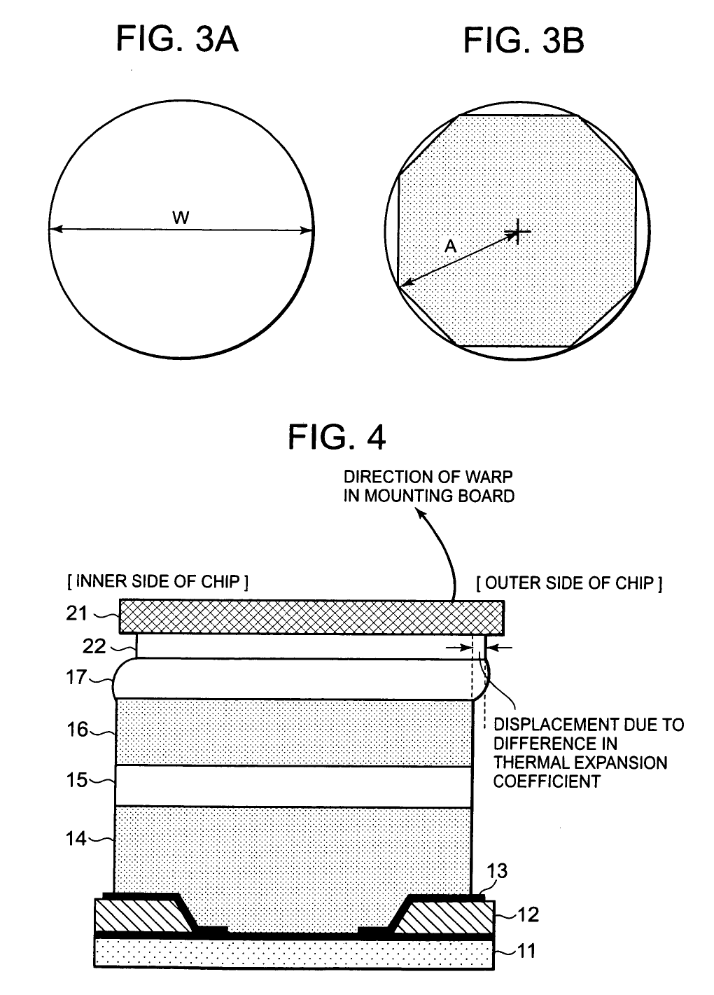

FIGS. 3A and 3B are plan views of the columnar bump seen from above. The shape of the columnar bump seen from above may be substantially circular as illustrated in FIG. 3A, and may be a polygon as illustrated in FIG. 3B. FIG. 3B illustrates a case in which the shape of the columnar bump seen from above is an octagon. When the high melting point metal layers formed of Cu or the like are formed in the shape of a polygon as illustrated in FIG. 3B, instead of Equation (3), Equation (4) is satisfied.

L1≦A (4)

where A is a distance from a center of the polygon to a vertex which is the farthest from the center.

As described in the above, this can prevent, when the second solder 17 is melted, the melted solder from going around the periphery of the top to the side of the columnar bump, and thus, the horizontal spread of the solder can be suppressed.

FIG. 4 illustrates a state of the semiconductor device after the mounting. As illustrated in FIG. 4, the second solder 17 as the uppermost layer of the columnar bump formed as illustrated in FIG. 2 and an auxiliary solder 22 formed on a substrate pad 21 of the mounting board are disposed so as to be opposed to each other, and reflow is carried out under temperature conditions in which only the second solder 17 is melted. It is to be noted that a low melting point solder which is melted at a temperature that is substantially similar to the melting point of the second solder 17 is used as the auxiliary solder 22 on the side of the mounting board. In this way, the semiconductor device is flip-chip mounted on the mounting board.

Conventionally, in flip-chip mounting, stresses due to a difference in thermal expansion coefficient between the chip and the mounting board and due to a warp in the mounting board because of heat cause breakage of the bump. However, according to the present invention, the ratio of the solder in the bump structure is made larger, and hence, when stresses are produced in flip-chip mounting, the stresses can be alleviated by ductility of the solder layers. More specifically, displacement due to the difference in thermal expansion coefficient between the chip and the mounting board and due to the warp in the mounting board because of heat can be made smaller. This makes it possible to prevent the breakage of the bump.

Further, the structure is a lamination structure in which the high melting point metal layers and the solders are alternately laminated, and the solder layer which is the lower layer also acts as an alleviator of the stresses. In this way, the stresses can be alleviated by the whole bump, and the breakage of the bump can be prevented more effectively than in a case in which only an upper portion of the bump alleviates the stresses.

The second high melting point metal layer 16 is formed under the second solder 17 as the uppermost layer which is melted in the reflow. The second high melting point metal layer 16 is not completely alloyed with the second solder 17, which effectively maintains the shape of the columnar bump. Further, by restricting the ratio of the solder in the columnar bump and maintaining a certain ratio of the high melting point metal whose resistance is low such as Cu, the increase in resistance of the bump portion can be suppressed to a minimum.

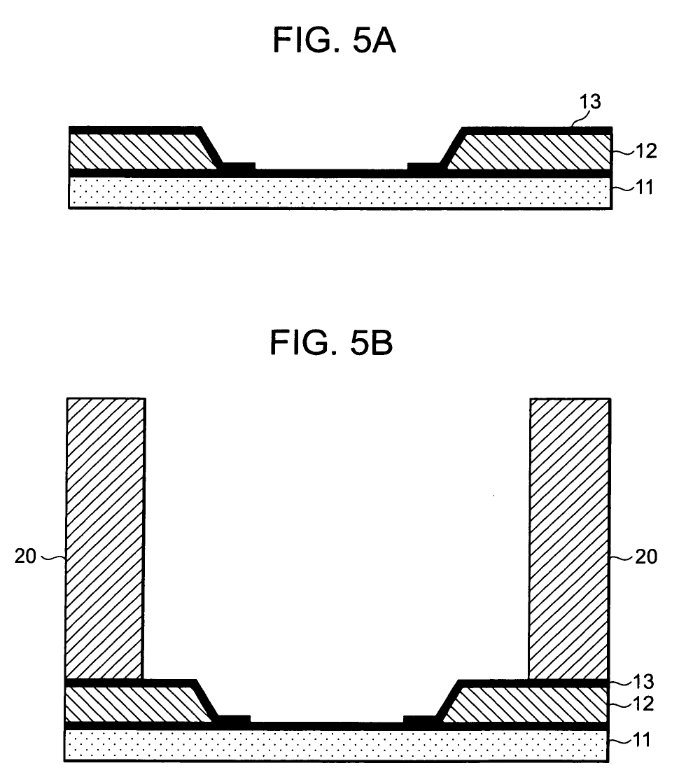

Here, a method of manufacturing the semiconductor device 10 according to this embodiment is now described with reference to FIGS. 5A to 7A. FIGS. 5A to 7A are cross-sectional views for describing the method of manufacturing the semiconductor device 10 according to this embodiment.

First, similarly to a conventional process, the polyimide 12 is formed on the uppermost layer metal 11, and patterning is carried out so as to expose a part of the uppermost layer metal 11. Then, the sputtered film 13 to be a conductive path in plating is formed on the uppermost layer metal 11 and the polyimide 12. In this way, a structure illustrated in FIG. 5A is obtained.

After that, a thick photoresist (PR) 20 is formed, patterning is carried out, and an opening is formed in a region in which the columnar bump is to be formed. The photoresist 20 is formed so that its thickness is larger than a height H of the columnar bump to be formed in a later process (the sum of the heights of the first high melting point metal layer 14, the first solder 15, the second high melting point metal layer 16, and the second solder 17, i.e., H=M1+h1+M2+L1). The sputtered film 13 is exposed in the opening in the photoresist 20. In this way, a structure illustrated in FIG. 5B is obtained.

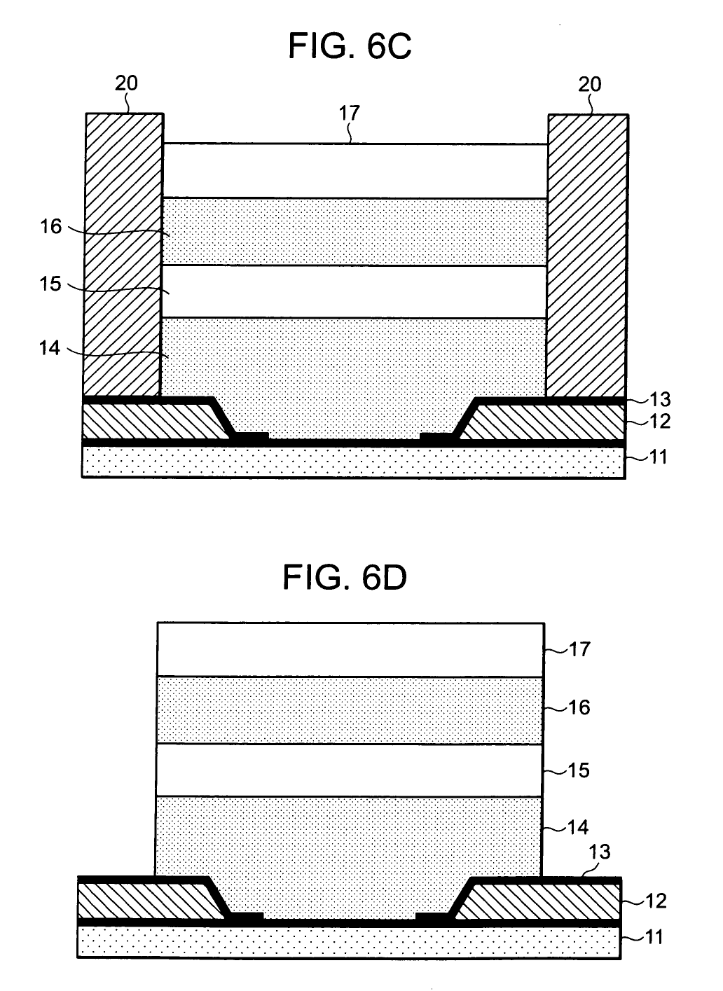

Then, with the photoresist 20 being formed on the sputtered film 13, high melting point metal layers and solders are alternately laminated to form the columnar bump. In this embodiment, four layers of the first high melting point metal layer 14, the first solder 15, the second high melting point metal layer 16, and the second solder 17 are grown by plating in succession without removing the photoresist 20. In this way, a structure illustrated in FIG. 6C is obtained.

Here, as the first high melting point metal layer 14 and the second high melting point metal layer 16, a high melting point metal whose resistance is lower than (whose conductivity is higher than) those of the solders and which is not melted at the temperature of the reflow (400° C. or lower) may be used. Further, as the first solder 15, a solder whose melting point is higher than that of the second solder 17 as the uppermost layer is used so that the first solder 15 is not melted in the reflow process at the end of the bump forming process.

For example, when a solder whose melting point is about 230° C. is used as the second solder 17, a solder whose melting point is 280° C. or higher is used as the first solder 15. When a solder whose melting point is about 180° C. is used as the second solder 17, a solder whose melting point is 230° C. or higher is used as the first solder 15. In particular, it is preferable that a high melting point solder containing a soft metal such as lead (Pb) be used as the first solder 15.

It is to be noted that the growth thicknesses of the respective layers satisfy, as described in the above, Equations (1) and (2), and, depending on the shape of the columnar bump seen from above, Equation (3) or (4). This makes it possible to suppress the increase in resistance due to the columnar bump, and to, while maintaining the shape of the columnar bump, prevent a short circuit between bumps.

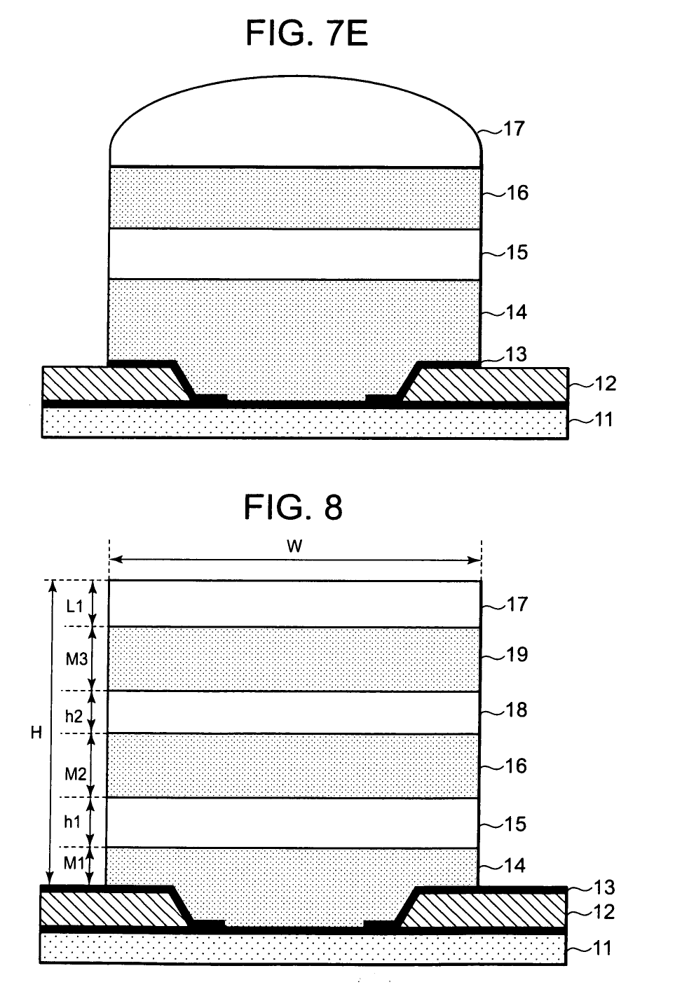

After the plating process is completed, the photoresist 20 is removed to obtain a structure illustrated in FIG. 6D. After that, the unnecessary sputtered film 13 outside the columnar bump is removed by wet etching. Then, reflow is carried out at a temperature at which only the second solder 17 is melted. This makes only the second solder 17 melted once, and, as illustrated in FIG. 7E, the formation of the bump is completed. In mounting, reflow is carried out under temperature conditions in which only the second solder 17 is melted. This enables flip-chip mounting while maintaining the shape of the columnar bump.

As described in the above, according to the present invention, when stresses are produced in flip-chip mounting, the stresses can be alleviated by the ductility of the solders, and the breakage of the bump can be prevented. Further, the shape of the columnar bump can be maintained even after the mounting process, and it is possible to suppress shortening of the distance between the chip and the mounting board in flip-chip mounting. Still further, the increase in resistance of the columnar bump can be suppressed to a minimum.

### Second Embodiment

A semiconductor device according to a second embodiment of the present invention is now described with reference to FIG. 8. FIG. 8 is a cross-sectional view illustrating a structure of a columnar bump before reflow of the semiconductor device according to this embodiment. As illustrated in FIG. 8, a semiconductor device 10 according to this embodiment includes an uppermost layer metal 11, a polyimide 12, a sputtered film 13, a first high melting point metal layer 14, a first solder 15, a second high melting point metal layer 16, a second solder 17, a third solder 18, and a third high melting point metal layer 19.

In this embodiment, the columnar bump has a lamination structure in which the first high melting point metal layer 14, the first solder 15, the second high melting point metal layer 16, the third solder 18, the third high melting point metal layer 19, and the second solder 17 are laminated in the stated order from the bottom. More specifically, in this embodiment, the columnar bump has a structure in which three two-layer structures each having a high melting point metal layer and a solder laminated therein are stacked. In other words, three high melting point metal layers and three solder layers are alternately laminated.

As the third high melting point metal layer 19, similarly to the case of the first high melting point metal layer 14 and the second high melting point metal layer 16, a high melting point metal whose resistance is lower than (whose conductivity is higher than) those of the solders may be used. As the first solder 15 and the third solder 18, a solder having a melting point which is higher than that of the second solder 17 as an uppermost layer is used so as not to be melted in a reflow process at the end of a bump forming process. This makes it possible to maintain a shape of the columnar bump.

As illustrated in FIG. 8, it is assumed that a thickness of the first high melting point metal layer 14, a thickness of the second high melting point metal layer 16, and a thickness of the third high melting point metal layer 19 are M1, M2, and M3, respectively. Further, it is assumed that a thickness of the first solder 15, a thickness of the third solder 18, and a thickness of the second solder 17 are h1, h2, and L1, respectively. It is to be noted that a height H of the whole columnar bump is substantially the same as that of the first embodiment.

For the purpose of suppressing an increase in resistance, the thickness (volume) of the high melting point metal layers is made to be equal to or larger than the thickness (volume) of the solders. More specifically, a sum of the thicknesses of the first high melting point metal layer 14, the second high melting point metal layer 16, and the third high melting point metal layer 19 is made to be equal to or larger than a sum of the thicknesses of the first solder 15, the third solder 18, and the second solder 17 to satisfy Equation (5).

M1+M2+M3≧h1+h2+L1 (5)

This makes it possible to suppress the increase in resistance due to the columnar bump.

The thickness L1 of the second solder 17 satisfies Equation (3) or (4) described in the above depending on the shape of the columnar bump seen from above. This makes it possible to suppress horizontal spread of the solder and to prevent a short circuit between bumps.

The semiconductor device having the columnar bump of the lamination structure can be formed by a process similar to that described in the above. More specifically, a photoresist 20 is formed so as to be higher than the height H of the columnar bump (the sum of the heights of the first high melting point metal layer 14, the first solder 15, the second high melting point metal layer 16, the second solder 17, the third solder 18, and the third high melting point metal layer 19, i.e., H=M1+h1+M2+h2+M3+L1), patterning is carried out, and an opening is formed in a region in which the columnar bump is to be formed.

Then, with the photoresist 20 being formed on the sputtered film 13, high melting point metal layers and solders are alternately laminated to form the columnar bump. In this embodiment, six layers of the first high melting point metal layer 14, the first solder 15, the second high melting point metal layer 16, the third solder 18, the third high melting point metal layer 19, and the second solder 17 are grown by plating in succession without removing the photoresist 20.

It is to be noted that the number of the laminated high melting point metal layers and solders is not limited thereto. More than three high melting point metal layers and more than three solders may be formed. In that case, as solder layers other than the uppermost layer, a solder having a melting point which is higher than that of the solder layer as the uppermost layer is used. Then, the thicknesses of the respective layers are made to satisfy Equation (6).

M1+M2+M3+ . . . +MX≧h1+h2+ . . . +L1 (6)

where the number of the laminated high melting point metal layers or solders is X.

The thickness L1 of the second solder 17 satisfies Equation (3) or (4) described in the above depending on the shape of the columnar bump seen from above.

### Third Embodiment

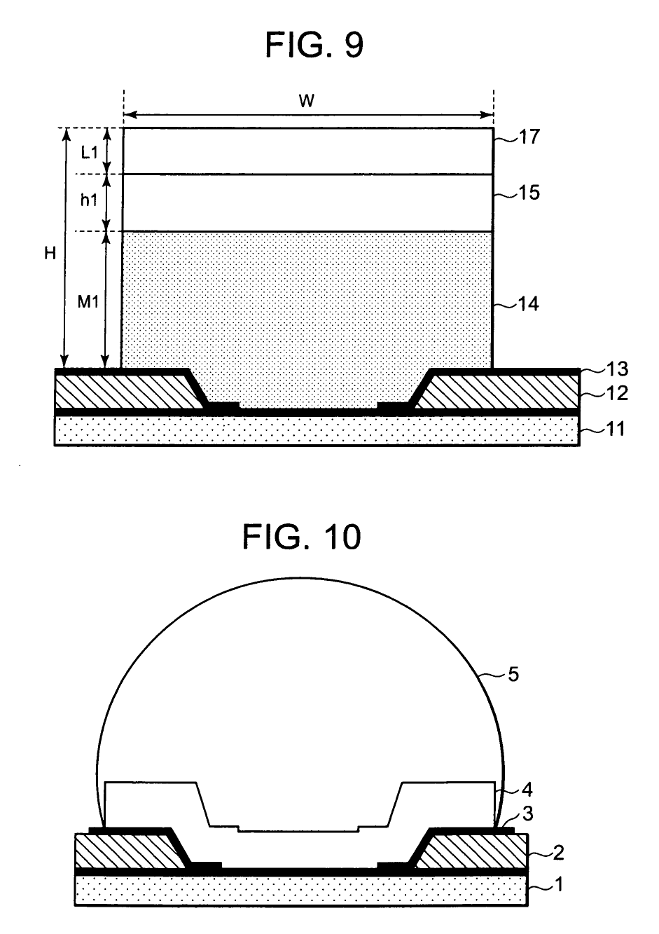

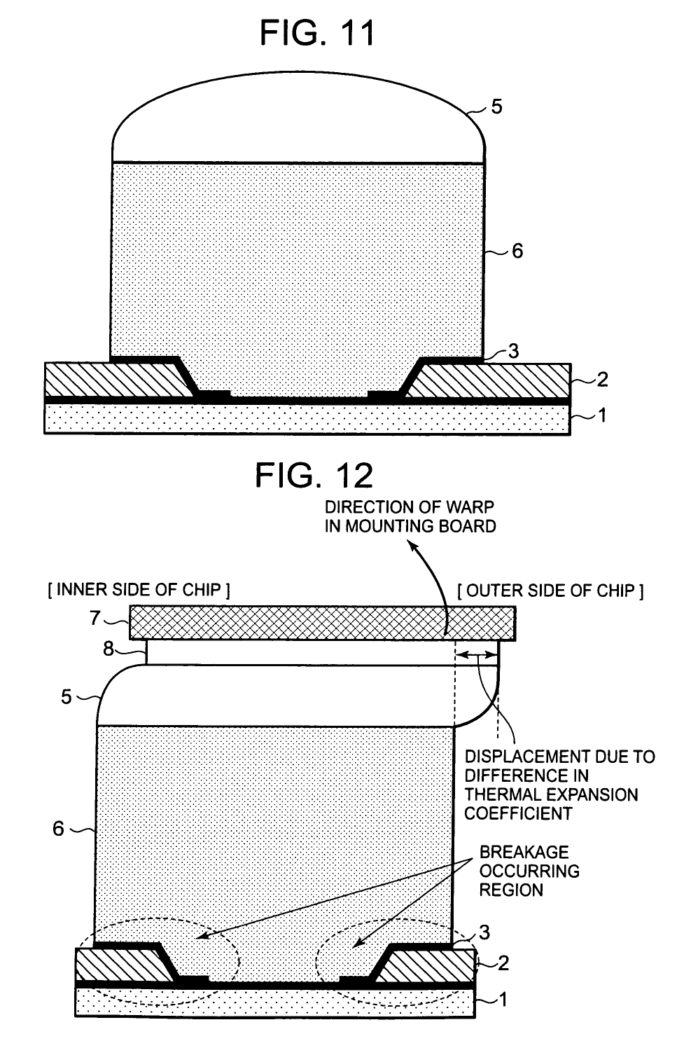

A semiconductor device according to a third embodiment of the present invention is now described with reference to FIG. 9. FIG. 9 is a cross-sectional view illustrating a structure of a columnar bump before reflow of the semiconductor device according to this embodiment. As illustrated in FIG. 9, a semiconductor device 10 according to this embodiment includes an uppermost layer metal 11, a polyimide 12, a sputtered film 13, a first high melting point metal layer 14, a first solder 15, and a second solder 17.

While, in the first and second embodiments, the high melting point metal layers and the solders are alternately laminated, in the third embodiment, such a structure is employed in which the high melting point metal layer formed of Cu or the like whose thickness is equal to or larger than a half of a height (H) of the bump is formed as a lower layer, and the first solder 15 and the second solder 17 are formed in succession as an upper layer.

In this embodiment, also, as the first solder 15, a solder whose hardness is different from that of the second solder 17 as an uppermost layer and which has a melting point that is higher than that of the second solder 17 is used. In particular, it is preferable that the first solder 15 be a metal layer which is softer than the first high melting point metal layer 14.

As illustrated in FIG. 9, it is assumed that a thickness of the first high melting point metal layer 14, a thickness of the first solder 15, and a thickness of the second solder 17 are M1, h1, and L1, respectively. It is to be noted that the height H of the whole columnar bump is substantially the same as that of the first embodiment. In this embodiment, the thicknesses of the respective layers satisfy Equation (7).

M1>h1+L1 (7)

This makes it possible to suppress an increase in resistance due to the columnar bump.

The thickness L1 of the second solder 17 satisfies Equation (3) or (4) described in the above depending on the shape of the columnar bump seen from above.

As described in the above, in the third embodiment, by adding the first solder 15 whose melting point is higher than that of the second solder 17 between the first high melting point metal layer 14 and the second solder 17, the height of the bump can be maintained. Further, an amount of the solders which are mixed with each other in reflow can be suppressed to a minimum, whereby horizontal spread of the bump beyond its original shape caused by being melted can be suppressed.

As described in the above, according to the present invention, by providing a solder between high melting point metal layers, breakage of a bump can be suppressed, and thus, the yield and the reliability of a semiconductor device can be improved. Further, the columnar bump according to the present invention can be manufactured according to a conventional plating process without increasing the number of the photoresist, and thus, manufacture thereof with a simple process is possible.

Further, the melting point of the solder as the uppermost layer is lower than that of other solders, and hence the height of the bump can be maintained even after the reflow process. Further, by appropriately determining the amount of the solder as the uppermost layer, the horizontal spread of the bump due to the melted solder can be suppressed, which is effective in decreasing the bump pitch and the chip size. Still further, by appropriately determining the thicknesses (volumes) of the high melting point metal layers and the solder layers, the increase in resistance due to the bump can be suppressed to a minimum.

What is claimed is:

1. A semiconductor device, comprising:
an electrode pad; and
a columnar bump formed on the electrode pad, the columnar bump comprising:
a first high melting point metal layer formed on the electrode pad;
a first solder formed on the first high melting point metal layer;
a second high melting point metal layer formed on the first solder; and
a second solder which is formed on the second high melting point metal layer and is connected to an external.

2. A semiconductor device according to claim 1, wherein a thickness of the first high melting point metal layer is equal to or larger than a thickness of the second high melting point metal layer.

3. A semiconductor device according to claim 1, wherein a sum of a thickness of the first high melting point metal layer and a thickness of the second high melting point metal layer is equal to or larger than a sum of a thickness of the first solder and a thickness of the second solder.

4. A semiconductor device according to claim 1, wherein the thickness of the second solder is equal to or smaller than a half of a width of the columnar bump.

5. A semiconductor device according to claim 1, wherein the columnar bump further comprises:
a third solder formed between the second high melting point metal layer and the second solder; and
a third high melting point metal layer formed between the third solder and the second solder.

6. A semiconductor device, comprising:
an electrode pad; and
a columnar bump formed on the electrode pad, the columnar bump comprising:
a first high melting point metal layer which is formed on the electrode pad, and occupies a half or more of a volume of the columnar bump;
a first solder formed on the first high melting point metal layer; and
a second solder which is formed on the first solder and is connected to an external.

7. A semiconductor device according to claim 1, wherein the first solder has a melting point that is higher than a melting point of the second solder.

8. A semiconductor device according to claim 5, wherein each of the first solder and the third solder has a melting point that is higher than a melting point of the second solder.

9. A method of manufacturing a semiconductor device, comprising forming a columnar bump on an electrode pad, the forming the columnar bump comprising:
forming a first high melting point metal layer on the electrode pad;
forming a first solder on the first high melting point metal layer;
forming a second high melting point metal layer on the first solder; and
forming a second solder on the second high melting point metal layer, the second solder being connected to an external.

10. A method of manufacturing a semiconductor device according to claim 9, wherein the first high melting point metal layer is formed to have a thickness that is equal to or larger than a thickness of the second high melting point metal layer.

11. A method of manufacturing a semiconductor device according to claim 9, wherein the first high melting point metal layer and the second high melting point metal layer are formed so that a total thickness of high melting point metal layers comprising the first high melting point metal layer and the second high melting point metal layer is equal to or larger than a total thickness of solders comprising the first solder and the second solder.

12. A method of manufacturing a semiconductor device according to claim 9, wherein the second solder is formed to have a thickness that is equal to or smaller than a half of a width of the columnar bump.

13. A method of manufacturing a semiconductor device according to claim 9, wherein the forming the columnar bump further comprises:
forming a third solder between the second high melting point metal layer and the second solder; and
forming a third high melting point metal layer between the third solder and the second solder.

14. A method of manufacturing a semiconductor device, comprising forming a columnar bump on an electrode pad, the forming the columnar bump comprising:
forming a first high melting point metal layer on the electrode pad, the first high melting point metal layer occupying a half or more of a volume of the columnar bump;
forming a first solder on the first high melting point metal layer; and
forming a second solder on the first solder, the second solder being connected to an external.

15. A method of manufacturing a semiconductor device according to claim 9, wherein the first solder has a melting point that is higher than a melting point of the second solder.

16. A method of manufacturing a semiconductor device according to claim 13, wherein each of the first solder and the third solder has a melting point that is higher than a melting point of the second solder.

17. A semiconductor device, comprising:
an electrode pad;
a high melting point metal layer formed on the electrode pad;
a first metal layer formed on the high melting point metal layer; and
a second metal layer which is formed on the first metal layer, and has a hardness different from a hardness of the first metal layer,
the high melting point metal layer, the first metal layer, and the second metal layer forming a columnar bump.

18. A semiconductor device according to claim 17, wherein the first metal layer is softer than the high melting point metal layer.
